(19) United States
(12) Patent Application Publication
(10) Pub. No.: US 2015/0192145 A1
(43) Pub. Date: Jul. 9, 2015

(54) COOLING FAN APPARATUS

(71) Applicant: Samsung Electronics Co., Ltd., Suwon-si (KR)

(72) Inventor: Kyung-ha KOO, Seoul (KR)

(73) Assignee: Samsung Electronics Co., Ltd., Suwon-si (KR)

(21) Appl. No.: 14/322,968

(22) Filed: Jul. 3, 2014

(30) Foreign Application Priority Data
Jan. 3, 2014 (KR) 10-2014-0000894

(51) Int. Cl. F04D 29/42; H05K 7/20; G06F 1/20; F04D 17/08

(52) U.S. Cl. CPC F04D 29/424; F04D 17/08; H05K 7/20145; G06F 1/203

(57) ABSTRACT

A cooling fan apparatus is arranged between upper and lower structures in an electronic device and includes a housing having upper and lower surfaces respectively spaced apart from the upper and lower structures at first and second intervals, first and second air flow holes respectively formed on the upper and lower surfaces, and an air discharge port formed on a side surface thereof, a fan rotatably arranged on an inner side of the housing, a first air flow resistance reduction portion formed on at least a portion adjacent to an edge of the upper surface of the housing to be spaced apart from the upper structure at a third interval that is wider than the first interval, and a second air flow resistance reduction portion formed on at least a portion adjacent to an edge of the lower surface of the housing to be spaced apart from the lower structure at a fourth interval that is wider than the second interval.

### CROSS-REFERENCE TO RELATED APPLICATIONS

This application claims priority under 35 U.S.C. §119(a) from Korean Patent Application No. 10-2014-0000894, filed on Jan. 3, 2014, in the Korean Intellectual Property Office, the disclosure of which is incorporated herein by reference in its entirety.

### BACKGROUND OF THE INVENTION

1. Field of the Invention

The present disclosure relates to a cooling fan apparatus, and more particularly, to a cooling fan apparatus that is arranged between an upper structure and a lower structure of an electronic device to cool various kinds of electronic elements provided in the electronic device.

2. Description of the Related Art

In general, a cooling fan apparatus that is used to cool an electronic device having a relatively thin thickness, such as a laptop PC, is mainly provided with a centrifugal fan for inflow and discharge of air.

Such a cooling fan apparatus cools the electronic device in a manner that a fan arranged inside a housing thereof is rotated to generate an ambient air flow, and this ambient air flow causes an air flow around heat generation components in the electronic device to cool the heat generation components or guides an air flow around predetermined heat dissipation fins mounted to cool the heat generation components to cool the heat generation components.

In a case where the above-described cooling fan apparatus is installed in a thin electronic device, it is arranged between upper and lower structures to make an air flow into a gap space between the upper and lower structures and to discharge the air through one side surface of the housing.

According to the cooling fan apparatus as described above, however, since a gap space between the upper and lower structures is narrow and an edge portion of the housing is formed at a right angle, a high air flow resistance, such as vena contracta, occurs in an edge portion of the housing.

Due to the high air flow resistance, an air flow rate through the cooling fan apparatus is decreased, and thus an air injection rate for cooling is also decreased to deteriorate a cooling efficiency of the cooling fan apparatus.

### SUMMARY OF THE INVENTION

The present general inventive concept provides a cooling fan apparatus which can increase an air flow rate by forming an air flow resistance reduction portion in at least one portion of a place that is adjacent to edges of upper and lower surfaces of a housing thereof.

Additional features and utilities of the present general inventive concept will be set forth in part in the description which follows and, in part, will be obvious from the description, or may be learned by practice of the general inventive concept.

The foregoing and/or other features and utilities of the present general inventive concept may be achieved by providing a cooling fan apparatus arranged between upper and lower structures of an electronic device, the cooling fan apparatus including a housing having upper and lower surfaces that are respectively spaced apart from the upper and lower structures at first and second intervals, first and second air flow holes respectively formed on the upper and lower surfaces, and an air discharge port formed on a side surface thereof, a fan rotatably arranged in an inner side of the housing, a first air flow resistance reduction portion formed on at least a portion of the housing that is adjacent to an edge of the upper surface of the housing to be spaced apart from the upper structure at a third interval that is wider than the first interval, and a second air flow resistance reduction portion formed on at least another portion of the housing that is adjacent to another edge of the lower surface of the housing to be spaced apart from the lower structure at a fourth interval that is wider than the second interval.

The first and second air flow resistance reduction portions may be downwardly inclined toward the edges of the upper and lower surfaces of the housing, respectively.

The first and second air flow resistance reduction portions may be formed with a step height from the edges of the upper and lower surfaces of the housing toward center sides of the upper and lower surfaces of the housing.

Each of the first and second air flow resistance reduction portions may include a horizontal section connecting with the edge and an inclined section connecting with the horizontal section.

The inclined section of the first or second air flow resistance reduction portions may be downwardly inclined toward the horizontal section.

A side surface of the housing may be formed to be curved convexly to an outside.

Edges of the upper and lower surfaces of the housing may be formed to be rounded.

The housing may include an upper housing including the first air flow hole and the first air flow resistance reduction portion; and a lower housing including the second air flow hole and the second air flow resistance reduction portion, wherein the air discharge port is formed by a combination of the upper and lower housings.

The foregoing and/or other features and utilities of the present general inventive concept may also be achieved by providing a cooling fan apparatus arranged between two structures that are arranged at an interval in an electronic device to make an air flow into both surfaces thereof that respectively face the two structures and to discharge the air through one side surface thereof, the cooling fan apparatus including a fan and a housing in which the fan is rotatably built and which has first and second air flow resistance reduction portions formed on portions thereof that are adjacent to edges of the both surfaces that respectively face the two structures.

The foregoing and/or other features and utilities of the present general inventive concept may also be achieved by providing a cooling fan apparatus usable with an electronic device, the cooling fan apparatus including a fan and a housing disposed on a reference plane of the electronic apparatus to accommodate the fan, the housing including one or more air flow holes formed on corresponding surfaces of the housing; an air discharge hole formed along a first peripheral edge portion of the housing to discharge the air in an air outlet portion, and one or more air flow resistance reduction portions formed along a second peripheral edge portion of the housing in an air inlet portion, the second peripheral edge portion being longer than the first peripheral edge portion.

The one or more air flow resistance reduction portions may have a variable distance from the reference plane and a corresponding distal end of the second peripheral edge portion.

The one or more air flow resistance reduction portions may be disposed between the air inlet portion and the corresponding air flow holes and may include an inclined portion to have a height increasing according to a distance from the air inlet portion.

The one or more air flow resistance reduction portions and the second peripheral edge portion may have a U shape having opposite ends disposed away from the air inlet portion farther than other portion disposed between the opposite ends.

The second peripheral edge portion of the housing may have opposite ends to meet corresponding ends of the first peripheral edge portion of the housing.

The electronic device may include two portions spaced apart from each other to provide a space, the housing may be disposed in the space and may include the surfaces and the one or more air flow reduction portions extended from the corresponding surface in a direction from the air outlet portion to the air inlet portion, and the one or more air flow resistance reduction portions may have a gap with the corresponding portion of the electronic device, the gap being variable according to a distance from a center of the fan.

### BRIEF DESCRIPTION OF THE DRAWINGS

These and/or other features and utilities of the present general inventive concept will become apparent and more readily appreciated from the following description of the embodiments, taken in conjunction with the accompanying drawings of which:

FIG. 1 is a schematic view illustrating a cooling fan apparatus usable with an electronic device according to an embodiment of the present general inventive concept;

FIG. 2 is an exploded perspective view illustrating the cooling fan apparatus of FIG. 1 according to an embodiment of the present general inventive concept;

FIG. 3 is a view explaining speed vectors an air flow formed between a cooling fan apparatus and an upper structure of an electronic device;

FIG. 4 is a view explaining speed vectors of an air flow formed between a cooling fan apparatus and an upper structure of an electronic device according to an embodiment of the present general inventive concept;

FIG. 5 is a partial side view illustrating a cooling fan apparatus according to an embodiment of the present general inventive concept;

FIG. 6 is a partial side view illustrating a cooling fan apparatus according to an embodiment of the present general inventive concept;

FIG. 7 is a view explaining speed vectors of an air flow formed between a cooling fan apparatus and an upper structure of an electronic device according to an embodiment of the present general inventive concept; and

FIG. 8 is a partial side view illustrating a cooling fan apparatus according to an embodiment of the present general inventive concept.

### DETAILED DESCRIPTION OF THE EMBODIMENTS

Reference will now be made in detail to the embodiments of the present general inventive concept, examples of which are illustrated in the accompanying drawings, wherein like reference numerals refer to the like elements throughout. The embodiments are described below in order to explain the present general inventive concept while referring to the figures.

The embodiments to be described hereinafter are exemplary to help a comprehensive understanding of the present disclosure, and the present disclosure can be implemented in diverse modifications differently from the embodiments to be described hereinafter. In describing the present disclosure, well-known element structures and technologies are not described in detail since they would obscure the disclosure in unnecessary detail. Further, in the drawings, to help the understanding of the present disclosure, sizes of some constituent elements may be exaggerated for clarity in explanation.

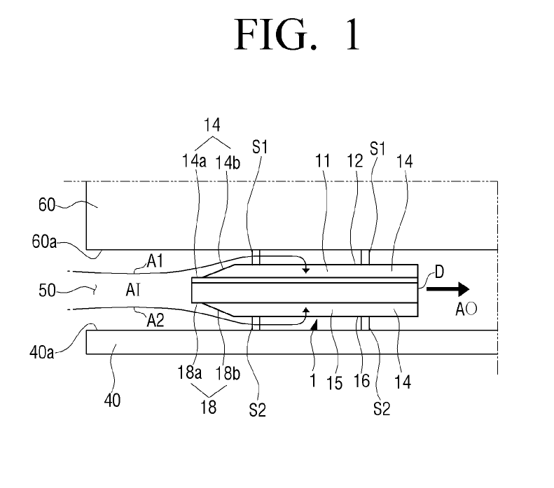

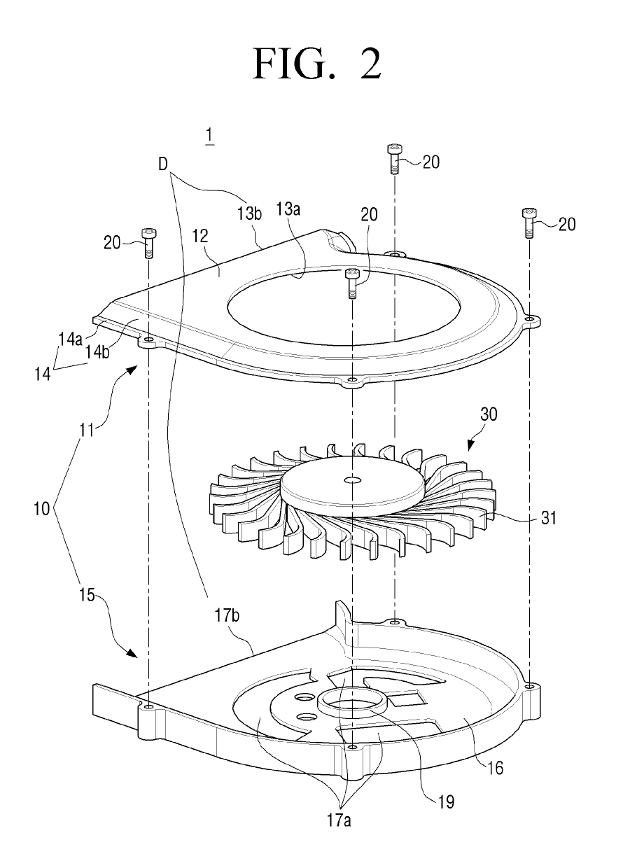

FIG. 1 is a schematic view illustrating a cooling fan apparatus 1 usable with an electronic device 2 according to an embodiment of the present general inventive concept. The cooling fan apparatus 1 may be arranged between lower and upper structures 40 and 60 of the electronic device 2. FIG. 2 is an exploded perspective view illustrating the cooling fan apparatus 1 of FIG. 1 according to an embodiment of the present general inventive concept.

The cooling fan apparatus 1 according to an embodiment of the present general inventive concept is arranged in an inside of the electronic device 2 (e.g., a laptop PC) to cool various kinks of electronic elements of the electronic device. The various elements of the electronic device 2 may be well known, and thus detail descriptions will be omitted. The electronic device 2 may have the lower and upper structures 40 and 60 to form an external appearance of the electronic device 2. And the electronic device 2 may include a keyboard element (not illustrated) disposed on the upper structure 60. The electronic device 2 may include a display element (not illustrated) and a user data/command input element (not illustrated) disposed on a portion of the electronic device. However, these elements are also well-known, and thus detail descriptions thereof. Hereinafter, the lower structure 40 may be referred to as a bottom portion 40, and the upper structure 60 may be referred to as a keyboard portion. However, the present general inventive concept is not limited thereto. It is possible that the lower structure 40 can be referred to as a first structure and the upper structure can be referred to as a second structure.

Referring to FIG. 1, the cooling fan apparatus 1 is arranged between the bottom portion 40 of the electronic device and the keyboard portion 60 at a predetermined interval H, that is, the cooling fan apparatus 1 is disposed in a space having the interval H between an upper surface 40a of the bottom portion 40 and a lower surface 60a of the keyboard portion 60. Also the cooling fan apparatus 1 is disposed on a reference plane defined by or parallel to the bottom portion 40 and/or the keyboard portion 60 of the electronic device 2. The reference plane may be a center plane disposed between the bottom portion 40 and the keyboard portion 60 or one of planes of the bottom portion 40 and the keyboard portion 60. The reference plane may be a plane corresponding to a major plane of a fan disposed in the cooling fan apparatus 1. The reference plane may be referred to a plane formed along an air inlet portion and an air outlet portion of the electronic device 2 through the cooling fan apparatus 1. In this case, a specific spacer S1 is arranged between at least a portion of an upper side of the cooling fan apparatus 1 and the keyboard portion 60 of the electronic device 2, and a specific spacer S2 is arranged between at least a portion of a lower side of the cooling fan apparatus 1 and the bottom portion 40 of the electronic device 2.

The spacers S1 and S2 have predetermined sizes so that air can flow between the upper side of the cooling fan apparatus 1 and the keyboard portion 60 of the electronic device 2 and between the lower side of the cooling fan apparatus 1 and the bottom portion 40 of the electronic device 2. The spacers S1 and S2 may be fixedly coupled to the cooling fan apparatus 1 and the portions of the electronic device 2 to fixedly support the cooling fan apparatus 1 between the lower and upper structures of the electronic device 2. The spacers S1 and S2 may be disposed at different locations of the cooling fan apparatus 1. The different locations may vary according to a user or design preference.

Referring to FIG. 2, the cooling fan apparatus 1 includes a housing 10 having an upper housing 11 as the upper side the cooling fan apparatus 1, a lower housing 15 as the lower side of the cooling fan apparatus 1, and a fan 30 rotatably installed in the housing 10.

A first air flow hole 13a having a diameter that is smaller than an entire diameter of the fan 30 is penetratingly formed on an upper surface 12 of the upper housing 11, and an opening 13b that forms an air discharge hole D with an opening 17b is formed on one side surface of the upper housing 11.

Further, a first air flow resistance reduction portion 14 is formed on the upper housing 11 to be recessed with a predetermined size along an edge of the upper surface 12 of the upper housing 11. The upper surface 12 and the first air flow resistance reduction portion 14 may form the upper side of the cooling fan apparatus 1. The first air flow resistance reduction portion 14 may be referred to an edge portion of the upper surface 12. That is, the first air flow resistance reduction portion 14 may be formed on a portion of the edge portion of the upper surface 12, and the edge portions of the upper and lower housings 11 and 15 may be coupled to each other when the upper and lower housings 11 and 15 are combined to form the cooling fan apparatus 1. It is also possible that the first air flow resistance reduction portion 14 and the supper surface 12 may be referred to as different elements disposed at different distances from the keyboard portion 60 of the electronic device 2.

The first air flow resistance reduction portion 14 may include a step height from an edge of the upper housing 11 toward a center portion of the upper housing 11. The center portion of the upper housing 11 may be a center portion of the fan 30. However, it is possible that the center portion of the upper housing 11 may not be the same center portion of the fan 30. The first air flow resistance reduction portion 14 may include a horizontal section 14a and an inclined section 14b connected between the horizontal section 14a and the edge of the upper surface 12 of the upper housing 11. In this case, the inclined section 14b may be downwardly inclined toward the horizontal section 14a from the edge of the upper surface 12. The horizontal section 14a is disposed between the edge of the upper housing 11 and the inclined section 14b. The upper housing 11 may have a first peripheral edge portion formed with the air discharge hole D and a second peripheral edge portion formed with the first air flow resistance reduction portion 14. The first peripheral edge portion corresponding to the air discharge hole D may have both ends having an angle with respect to the center portion of the upper housing 11, and the second peripheral edge portion corresponding to the first air flow resistance reduction portion 14 may have both ends having an angle with respect to the center of the upper housing 11. The angle of the first peripheral edge portion is smaller than the angle of the second peripheral edge portion. The first peripheral edge portion may be disposed on a line (or area) having a right angle with respect to an air discharge direction arrow AO in an air outlet portion, and the second peripheral edge portion may be disposed on a portion of a circle or a portion of a curve to correspond to an air inlet direction Al in an air inlet portion.

The lower housing 15 is formed substantially symmetrically with the upper housing 11, and is combined with the lower side of the upper housing 11. In this case, the upper and lower housing s 11 and 15 are separably combined with each other by a plurality of pieces 20 through coupling portions of the upper housing 11 and the lower housing 15. The coupling portions may be formed on the respective first and second peripheral portions of the upper and lower housing 11 and 15. It is also possible that the lower housing 15 may not be symmetrical with the upper housing 11. It is also possible that the lower housing 15 and the upper housing 11 may have a similar area parallel to a plane corresponding to the bottom and keyboard portions 40 and 60, and that the lower housing 15 and the upper housing 11 may have different heights in a direction perpendicular to the plane which is parallel to the air discharge direction arrow AO.

A second air flow hole 17a is penetratingly formed on a lower surface 16 (see FIG. 1) of the lower housing 15, and an opening 17b that forms the air discharge hole D together with the opening 13b of the upper housing 11 is formed on one side surface of the lower housing 15. The second air flow hole 17 may include a plurality of second air flow holes 17a as illustrated in FIG. 2. The first air flow hole 13a may have a shape or area different from the second air flow holes 17a. The first air flow hole 13a may have an area larger than a total area of the second air flow holes. However, the present general inventive concept is not limited thereto. It is possible that an air flowing area of the first air flow hole 13a may be similar to an air flowing area of the second air flow holes 17a.

Further, a second air flow resistance reduction portion 18 (see FIG. 1) is formed to be recessed with a predetermined size along an edge of a lower surface 16 of the lower housing 15. The lower surface 16 and the second air flow resistance reduction portion 18 may form the lower side of the cooling fan apparatus 1. The second air flow resistance reduction portion 18 may be referred to an edge portion of the lower surface 16. That is, the second air flow resistance reduction portion 18 may be formed on a portion of the edge portion of the lower surface 16, and the edge portions of the upper and lower housings 11 and 15 may be coupled to each other when the upper and lower housings 11 and 15 are combined to form the cooling fan apparatus 1. It is also possible that the second air flow resistance reduction portion 18 and the lower surface 16 may be referred to as different elements disposed at different distances from the bottom portion 40 of the electronic device 2.

Referring to FIG. 1, the second air flow resistance reduction portion 18 may include a step height from the edge of the lower surface 16 of the lower housing 15 toward a center portion of the lower housing 15. The center portion of the lower housing 15 may be a center portion of the fan 30. However, it is possible that the center portion of the lower housing 15 may not be the same center portion of the fan 30. The second air flow resistance reduction portion 18 may include a horizontal section 18a formed on an edge of the lower housing 15 and an inclined section 18b connected between the horizontal section 18a and the edge of the lower surface 16. In this case, the inclined section 18b may be downwardly inclined toward the horizontal section 18a from the edge of the lower surface 16. The horizontal section 18a is disposed between the edge of the lower housing 15 and the inclined section 14b. The lower housing 15 may have a first peripheral edge portion formed with the air discharge hole D and a second peripheral edge portion formed with the second air flow resistance reduction portion 18. The first peripheral edge portion corresponding to the air discharge hole D may have both ends having an angle with respect to the center portion of the lower housing 15, and the second peripheral edge portion corresponding to the second air flow resistance reduction portion 18 may have both ends having an angle with respect to the center of the lower housing 15. The angle of the first peripheral edge portion is smaller than the angle of the second peripheral edge portion. The first peripheral edge portion may be disposed on a line (or area) having a right angle with respect to the air discharge direction arrow AO, and the second peripheral edge portion may be disposed on a portion of a circle or a portion of a curve to correspond to the air inlet direction Al.

Further, an installation groove 19 may be formed on an inside of the lower housing 16 such that the fan 30 can be rotatably installed thereon.

The fan 30 may be a turbine fan having a plurality of wings 31 arranged along a circumference thereof at equal intervals.

As described above, according to an embodiment of the present general inventive concept, as illustrated in FIG. 1, a gap between the first air flow resistance reduction portion 14 and a lower surface 60a of the keyboard portion 60 is wider than a gap between the upper surface 12 of the upper housing 11 and the lower surface 60a of the keyboard portion 60. In the same manner, a gap between the second air flow resistance reduction portion 18 and an upper surface 40a of the bottom portion 40 is wider than a gap between the lower surface 12 of the lower housing 15 and the upper surface 40a of the bottom portion 40.

Accordingly, if the fan 30 is rotated, external air flows between the keyboard portion 60 and the bottom portion 40 in an air inlet direction Al due to a negative pressure that is generated around the first and second air flow holes 13a and 17a of the housing 10.

A first portion of the external air flows between the upper surface 12 of the upper housing 11 and the lower surface 60a of the keyboard portion 60 through the first air flow resistance reduction portion 14 along a first air path Al, and then flows into the housing 10 through the first air flow hole 13a. A second portion of the external air flows between the upper surface 16 of the lower housing 15 and the upper surface 40a of the bottom portion 40 through the second air flow resistance reduction portion 18 along a second air path A2, and then flows into the housing 10 through the second air flow hole 17a.

In this case, since the gap between the first air flow resistance reduction portion 14 and the lower surface 60a of the keyboard portion 60 is wider than the gap between the upper surface 12 of the upper housing 11 and the lower surface 60a of the keyboard portion 60, and the air that flows between the first air flow resistance reduction portion 14 and the lower surface 60a of the keyboard portion 60 moves to the first air flow hole 13a along the inclined section 14b of the first air flow resistance reduction portion 14, the flow resistance of the air becomes minimized at a position where the first air flow resistance reduction portion 14 is formed.

In the same manner, since the gap between the second air flow resistance reduction portion 18 and the upper surface 40a of the bottom portion 40 is wider than the gap between the lower surface 16 of the lower housing 15 and the upper surface 40a of the bottom portion 40, and the air that flows between the second air flow resistance reduction portion 18 and the upper surface 40a of the bottom portion 40 moves to the second air flow hole 18a along the inclined section 18b of the second air flow resistance reduction portion 18, the flow resistance of the air becomes minimized at a position where the second air flow resistance reduction portion 18 is formed.

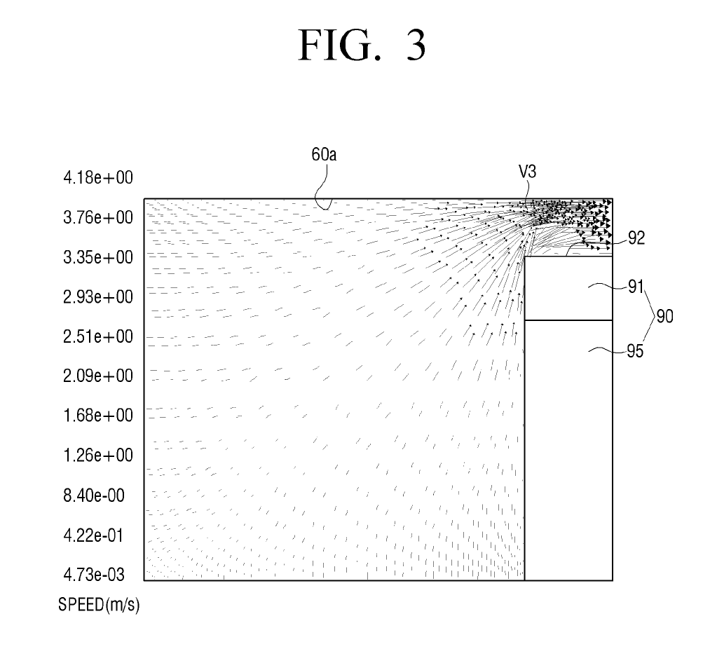

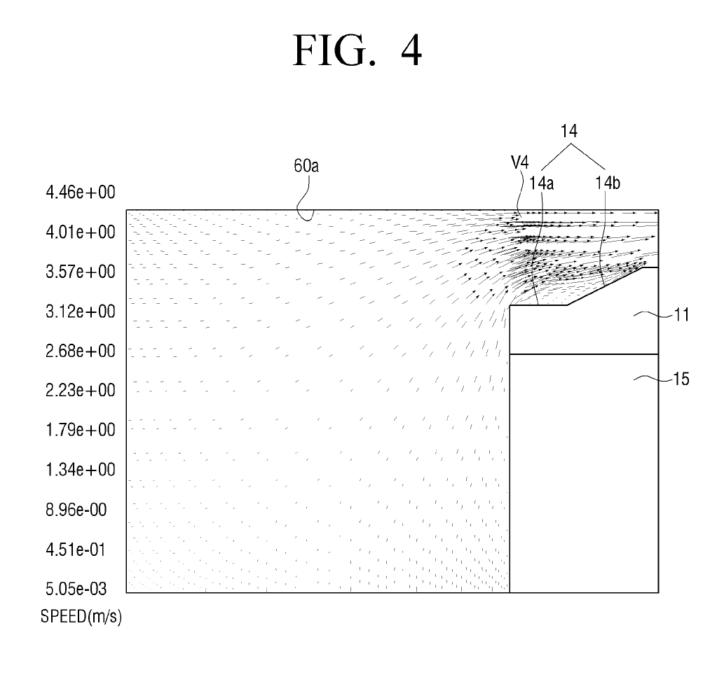

FIG. 3 is a view illustrating speed vectors V3 of an air flow formed between an upper structure of an electronic device and a conventional cooling fan apparatus 90, and FIG. 4 is a view illustrating speed vectors V4 of an air flow formed between an upper structure of an electronic device and a cooling fan apparatus according to an embodiment of the present general inventive concept.

Referring to FIG. 3, since a gap between a lower surface 60a of a keyboard portion and an upper surface 92 of an upper housing 91 coupled with a lower housing 95 is narrow and an edge portion of the upper housing 91 is formed to have a right angle, a high air flow resistance, such as vena contracta, occurs in the edge portion. This causes deterioration of air transport capability of the cooling fan apparatus 90.

However, referring to FIG. 4, the air that has passed the first air flow resistance reduction portion 14 has a minimum air flow resistance, and substantially a parallel air flow occurs between the lower surface 60a of the keyboard portion 60 and the upper surface 12 of the upper housing 11. In this case, the air flow speed around the first air flow resistance reduction portion 14 according to the present embodiment is about 4.01 e+00 m/s, whereas the air flow speed of the conventional cooling fan apparatus 90 is about 3.76e+00 m/s.

Since the air flow rate is typically in proportion to a cross-sectional area of a position through which the air passes and an air flow speed in the corresponding position, the cooling fan apparatus according to the present embodiment, which has a large cross-sectional area and maintains a high air flow speed in comparison to the conventional cooling fan apparatus, can increase an air inflow rate, and thus the performance of the electronic device can be improved according to the increase of the cooling efficiency.

Further, the cooling fan apparatus 1 according to the present embodiment can increase an air transport rate through the first and second air flow resistance reduction portions 14 and 18. If the fan 30 of the cooling fan apparatus 1 is made with the same size as the fan of the conventional cooling fan apparatus 90, a revolution of the fan 30 of the cooling fan apparatus 1 can be reduced in a state where the air flows at the same flow rate in comparison to the conventional cooling fan apparatus 90, and thus the noise of the fan 30 can be reduced.

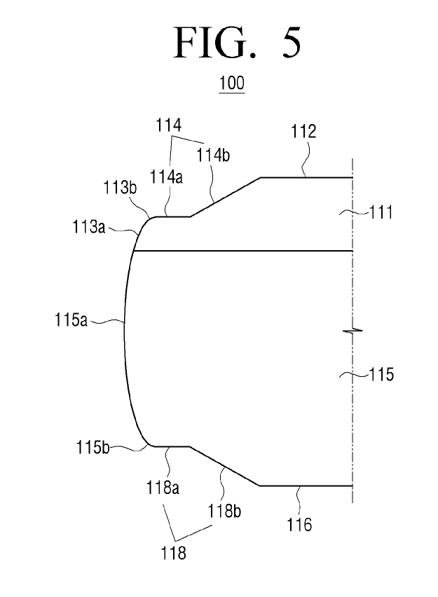

FIG. 5 is a partial side view illustrating a cooling fan apparatus 100 according to an embodiment of the present general inventive concept.

Referring to FIG. 5, the cooling fan apparatus 100 of FIG. 5 may be similar to the cooling fan apparatus 1 of FIG. 1 However, the cooling fan apparatus 100 of FIG. 5 is different from the cooling fan apparatus 1. That is, side surfaces 113a and 115a of upper and lower housings 111 and 115 are formed to be curved convexly. In this case, the side surfaces 113a and 115a of the upper and lower housings 111 and 115 may be configured to form a single circular arc when the upper and lower housings 111 and 115 are combined with each other.

Further, according to the present embodiment, edges 113b and 115b of the upper and lower housings 111 and 115 may be formed to be rounded with a predetermined curvature. Although the cooling fan apparatus 1 is described above to have peripheral portions and/or edges of the upper and lower housings 11 and 15 as a non-curve portion, it is possible that the peripheral portions and/or the edges of the upper and lower housings 11 and 15 can be formed to be rounded.

According to the present embodiment, the edges 113b and 115b and side surfaces 113a and 115a form a continuous curved surface to smoothly connect with first and second air flow resistance reduction portions 114 and 118 and to smoothly generate an air flow therealong without a sudden change of the air flow.

Accordingly, air that moves along the air inlet direction toward the upper and lower housings 111 and 115 is smoothly guided to the first and second air flow resistance reduction portions 114 and 118 along the edges 113b and 115b and the side surfaces 113a and 115a that form the curved surface as described above, and thus a fluid resistance of the air that is generated when the air flows into the first and second air flow resistance reduction portions 114 and 118 can be minimized.

In FIG. 5, a reference numeral 112 denotes an upper surface of the upper housing, a reference numeral 116 denotes a lower surface of the lower housing, reference numerals 114a and 118a denote horizontal sections, and reference numerals 114b and 118b denote inclined sections.

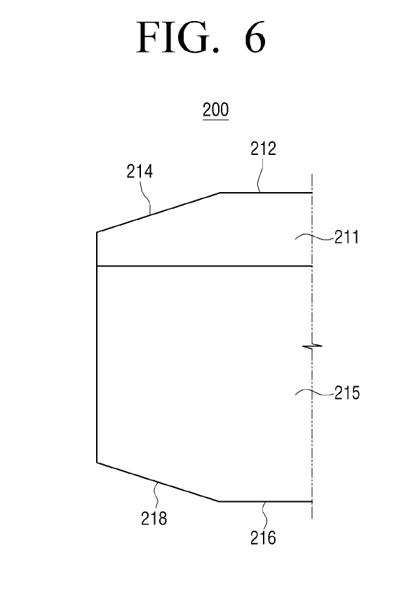

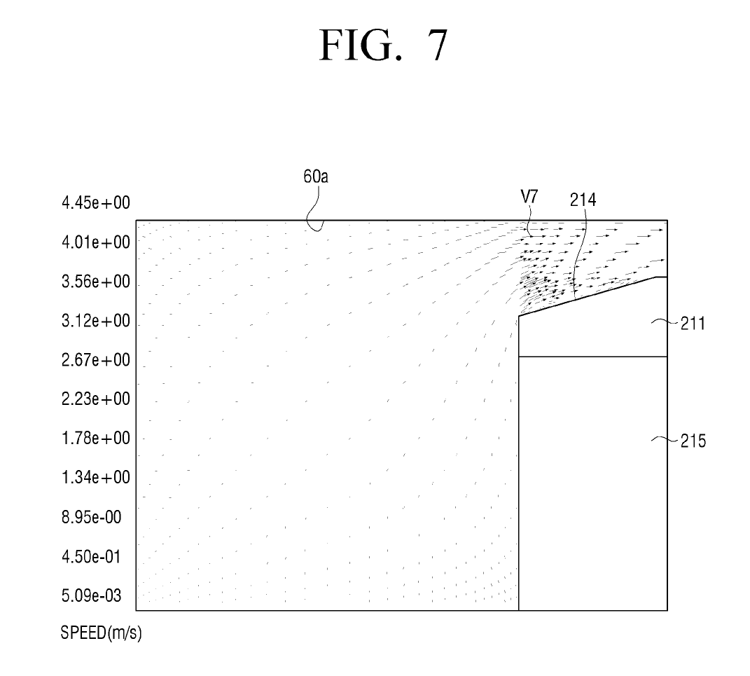

FIG. 6 is a partial side view illustrating a cooling fan apparatus 200 according to an embodiment of the present general inventive concept, and FIG. 7 is a view illustrating speed vectors V7 according to an air flow formed between the cooling fan apparatus 200 and an upper structure of an electronic device.

Referring to FIG. 6, the cooling fan apparatus 200 may be similar to the cooling fan apparatus 1 of FIG. 1. However, the cooling fan apparatus 200 may be different from the cooling fan apparatus 1 of FIG. 1. That is, first and second air flow resistance reduction portions 214 and 218 formed on upper and lower housings 211 and 215 may include inclined sections only without horizontal sections corresponding to the horizontal sections 14a and 18a of the cooling fan apparatus 1 of FIG. 1.

Referring to FIG. 7, according to the cooling fan apparatus 200, an air flow speed around the first air flow resistance reduction portion 214 is equal to (or similar to) an air flow speed of the cooling fan apparatus 1 of FIG. 1.

Accordingly, the cooling fan apparatus 200 according to the present embodiment can increase an air flow rate, compared to the conventional cooling fan apparatus, and also can increase the cooling efficiency in the electronic device.

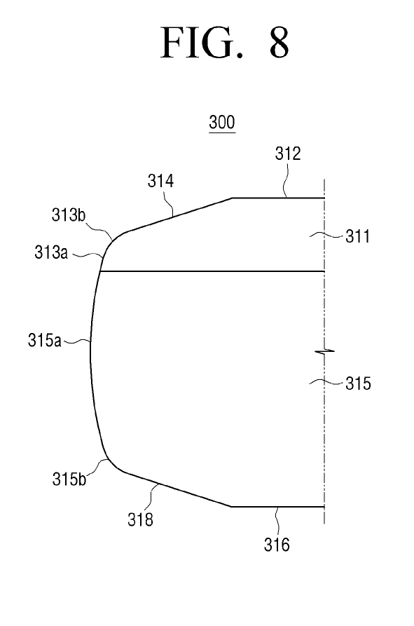

FIG. 8 is a partial side view illustrating a cooling fan apparatus 300 according to an embodiment of the present general inventive concept.

Referring to FIG. 8, the cooling fan apparatus 300 may be similar to the cooling fan apparatus 200 of FIG. 7. However, the cooling fan apparatus 300 may be different from the cooling fan apparatus 200. That is, side surfaces 313a and 315a of upper and lower housings 311 and 315 are formed to be curved convexly. In this case, the side surfaces 313a and 315a of the upper and lower housings 311 and 315 are configured to form a single circular arc when the upper and lower housings 311 and 315 are combined with each other.

Further, according to present embodiment, edges 313b and 315b of the upper and lower housings 311 and 315 may be formed to be rounded with a predetermined curvature. Referring to the cooling fan apparatus 200 of FIG. 7, it is possible that the edges of the upper and lower housings 211 and 215 can be formed to be rounded.

In FIG. 8, a reference numeral 312 denotes an upper surface of the upper housing 311, a reference numeral 314 denotes a first air flow resistance reduction portion, a reference numeral 316 denotes a lower surface of the lower housing 315, and a reference numeral 318 denotes a second air flow resistance reduction portion.

Although a few embodiments of the present general inventive concept have been shown and described, it will be appreciated by those skilled in the art that changes may be made in these embodiments without departing from the principles and spirit of the general inventive concept, the scope of which is defined in the appended claims and their equivalents.

What is claimed is:

1. A cooling fan apparatus arranged between upper and lower structures in an electronic device, comprising:
a housing having upper and lower surfaces that are respectively spaced apart from the upper and lower structures of the electronic device at first and second intervals, first and second air flow holes respectively formed on the upper and lower surfaces, and an air discharge port formed on a side surface thereof;
a fan rotatably arranged on an inner side of the housing;
a first air flow resistance reduction portion formed on at least a portion adjacent to an edge of the upper surface of the housing to be spaced apart from the upper structure at a third interval that is wider than the first interval; and
a second air flow resistance reduction portion formed on at least a portion adjacent to an edge of the lower surface of the housing to be spaced apart from the lower structure at a fourth interval that is wider than the second interval.

2. The cooling fan apparatus of claim 1, wherein the first and second air flow resistance reduction portions are downwardly inclined toward the edges of the upper and lower surfaces of the housing, respectively.

3. The cooling fan apparatus of claim 1, wherein the first and second air flow resistance reduction portions are formed with a step height from the edges of the upper and lower surfaces of the housing toward center portions of the upper and lower surfaces of the housing.

4. The cooling fan apparatus of claim 3, wherein each of the first and second air flow resistance reduction portions comprises a horizontal section and an inclined section connected between the horizontal section and the corresponding upper or lower surface.

5. The cooling fan apparatus of claim 4, wherein the inclined section of the first or second air flow resistance reduction portions is downwardly inclined toward the horizontal section.

6. The cooling fan apparatus of claim 1, wherein a side surface of the housing is formed to be curved convexly to an outside thereof.

7. The cooling fan apparatus of claim 2, wherein edges of the upper and lower surfaces of the housing are formed to be rounded.

8. The cooling fan apparatus of claim 1, wherein:
the housing comprises:
an upper housing including the first air flow hole and the first air flow resistance reduction portion, and
a lower housing including the second air flow hole and the second air flow resistance reduction portion; and
the air discharge port is formed by a combination of the upper and lower housings.

9. A cooling fan apparatus arranged between two structures that are arranged at an interval in an electronic device to make air flow into both surfaces thereof that respectively face the two structures and to discharge the air through one side surface thereof, comprising:
a fan; and
a housing in which the fan is rotatably built and which has first and second air flow resistance reduction portions formed on portions thereof that are adjacent to edges of the both surfaces that respectively face the two structures.

10. The cooling fan apparatus of claim 9, wherein the first and second air flow resistance reduction portions are inclined toward a peripheral end side of the housing.

11. The cooling fan apparatus of claim 9, wherein the first and second air flow resistance reduction portions are formed with a step height toward a peripheral end side of the housing.

12. The cooling fan apparatus as claimed in claim 11, wherein each of the first and second air flow resistance reduction portions comprises a horizontal section and an inclined section connected between the horizontal section and the corresponding surface.

13. The cooling fan apparatus of claim 9, wherein a peripheral surface of the housing is formed to be curved convexly to an outside thereof.

14. The cooling fan apparatus of claim 10, wherein edges of the both surfaces of the housing are formed to be rounded.

15. A cooling fan apparatus usable with an electronic device, comprising:
a fan; and
a housing disposed on a reference plane of the electronic apparatus to accommodate the fan, the housing comprising:
one or more air flow holes formed on corresponding surfaces of the housing;
an air discharge hole formed along a first peripheral edge portion of the housing to discharge the air in an air outlet portion; and
one or more air flow resistance reduction portions formed along a second peripheral edge portion of the housing in an air inlet portion, the second peripheral edge portion being longer than the first peripheral edge portion.

16. The cooling fan apparatus of claim 15, wherein the one or more air flow resistance reduction portions have a variable distance from the reference plane and a corresponding distal end of the second peripheral edge portion.

17. The cooling fan apparatus of claim 15, wherein the one or more air flow resistance reduction portions are disposed between the air inlet portion and the corresponding air flow holes and comprise an inclined portion to have a height increasing according to a distance from the air inlet portion.

18. The cooling fan apparatus of claim 15, wherein the one or more air flow resistance reduction portions and the second peripheral edge portion has a U shape having opposite ends disposed away from the air inlet portion farther than other portion disposed between the opposite ends.

19. The cooling fan apparatus of claim 15, wherein the second peripheral edge portion of the housing has opposite ends to meet corresponding ends of the first peripheral edge portion of the housing.

20. The cooling fan apparatus of claim 15, wherein:
the electronic device comprises two portions spaced apart from each other to provide a space;
the housing is disposed in the space and includes the surfaces and the one or more air flow reduction portions extended from the corresponding surface in a direction from the air outlet portion to the air inlet portion; and
the one or more air flow resistance reduction portions have a gap with the corresponding portion of the electronic device, the gap being variable according to a distance from a center of the fan.
